(19) United States
(12) Patent Application Publication
(10) Pub. No.: US 2026/0362890 A1
(43) Pub. Date: Nov. 12, 2026

(54) DISPLAY DEVICE

(71) Applicant: Qisda Corporation, Taoyuan City (TW)

(72) Inventors: PO-FU WU, Taoyuan City (TW); TSUNG-HSUN WU, Taoyuan City (TW)

(73) Assignee: Qisda Corporation, Taoyuan City (TW)

(21) Appl. No.: 19/669,441

(22) Filed: May 6, 2026

(30) Foreign Application Priority Data
May 12, 2025 (CN) 202510604797.4

(51) Int. Cl. H10H 29/85; H05K 1/189; H10H 29/14; H10H 29/853

(52) U.S. Cl. CPC H10H 29/857; H05K 1/189; H10H 29/14; H10H 29/853; H05K 2201/10128

(57) ABSTRACT

A display device is disclosed in the present invention, which includes a substrate, a wiring layer, a light-emitting unit, and a flexible circuit layer. The substrate has a light-receiving surface and a light-emitting surface disposed on opposite sides. The wiring layer is disposed on the light-receiving surface. The light-emitting unit is disposed on the light-receiving surface and configured to emit light into the substrate. The light-emitting unit includes a light-emitting chip and a pin, wherein the pin is electrically connected to the light-emitting chip and the wiring layer. The flexible circuit layer is electrically connected to the wiring layer and extends away from the light-receiving surface. Another display device is also disclosed, which includes a substrate, a wiring layer, a light-emitting unit, and a flexible circuit layer. The light-emitting unit includes a circuit board, a light-emitting chip, an encapsulation layer, and a pin.

### CROSS REFERENCE TO RELATED APPLICATION

This application claims the priority benefit of China Patent Application No. 202510604797.4, filed on May 12, 2025. The entirety of the mentioned above patent application is hereby incorporated by reference herein and made a part of this specification.

### BACKGROUND OF THE INVENTION

### 1. Field of the Invention

The present invention relates to a display device, specifically relates to a display device having light-emitting units configured to emit light toward the substrate.

### 2. Description of the Prior Art

With the advancement of display technology, large-scale and slim display devices have become an emerging trend. Compared to conventional backlit displays, light-emitting diode (LED) self-emissive displays require no additional backlight source, thereby enabling higher contrast ratios and thinner dimensions. However, as display sizes increase and individual LED unit sizes decrease, stricter material requirements are imposed on the substrate used to mount the LEDs.

Compared to traditional printed circuit board (PCB) substrates, glass substrates are considered a next-generation ideal substrate material due to their high mechanical strength, superior flatness, low thermal expansion, and high thermal conductivity.

Traditionally, LEDs are mounted on the front side of the substrate facing the user, while wiring and other control components are placed on the back side. However, unlike PCB substrates, which typically feature numerous via holes to connect circuits and components on both sides, drilling through glass substrates is technically challenging, costly, and low-yielding. An alternative approach is to arrange the wires toward the edge of the glass substrate and then redirect them to the back side, but these edge-exposed wires are prone to breakage due to collisions during panel splicing or installation. In addition, because the LEDs are oriented toward the user, they are exposed to potential contact or impact, requiring an additional protective layer to cover the front side of the LEDs, thereby increasing both manufacturing complexity and the thickness of the device.

Therefore, in the field of display devices, designing glass substrate structures that effectively protect wiring while reducing manufacturing difficulty remains a significant challenge.

### SUMMARY OF THE INVENTION

The present invention provides a display device emitting light from the backside of the light-penetrating substrate toward the user, wherein the substrate can support and protect the light-emitting unit. Since the light-emitting unit disposed on the backside of the substrate and directly emits light toward the substrate, the manufacturing process can be simplified and the thickness of the device can be reduced.

In an embodiment, the display device includes a substrate, a wiring layer, a light-emitting unit, and a flexible circuit layer. The substrate has a light-receiving surface and a light-emitting surface disposed on opposite sides. The wiring layer is disposed on the light-receiving surface. The light-emitting unit is disposed on the light-receiving surface and configured to emit light into the substrate. The light-emitting unit includes a light-emitting chip and a pin, wherein the pin is electrically connected to the light-emitting chip and the wiring layer. The flexible circuit layer is electrically connected to the wiring layer and extends away from the light-receiving surface.

In another embodiment, the display device includes a substrate, a wiring layer, a light-emitting unit, and a flexible circuit layer. The substrate has a light-receiving surface and a light-emitting surface disposed on opposite sides. The wiring layer is disposed on the light-receiving surface. The light-emitting unit is disposed on the light-receiving surface and configured to emit light into the substrate. The light-emitting unit includes a circuit board, a light-emitting chip, an encapsulation layer, and a pin. The circuit board has a first side facing toward the light-receiving surface. The light-emitting chip is disposed on the first side of the circuit board and electrically connected to the circuit board. The encapsulation layer covers a surface of the light-emitting chip facing toward the light-receiving surface. The pin is electrically connected to the light-emitting chip and the wiring layer. The flexible circuit layer is electrically connected to the wiring layer and extends away from the light-receiving surface.

### BRIEF DESCRIPTION OF THE DRAWINGS

FIG. 1 is an enlarged sectional view of a portion of the display device in an embodiment.

FIG. 2 is an enlarged sectional view of a portion of the display device in another embodiment.

FIG. 3A is a top view of the light-emitting unit in an embodiment.

FIG. 3B is a top view of the light-emitting unit in another embodiment.

FIG. 4 is a side sectional view of the light-emitting unit in another embodiment.

FIG. 5 is a schematic diagram of the display device in another embodiment.

### DETAILED DESCRIPTION OF THE INVENTION

To provide a further understanding of the objectives, structures, features, and functions of the present invention, various embodiments and accompanying drawings will be described below.

Certain terminology is used in the specification and claims to refer to specific components. A person having ordinary skill in the art should understand that manufacturers may use different terms to refer to the same component. The present specification and claims do not differentiate components based on the variation in nomenclature, but rather on their functional differences. The term “include” or “comprise” mentioned throughout the specification and claims is an open-ended phrase, therefore, it should be interpreted as “including but not limited to”.

In the accompanying drawings, the thicknesses of layers, films, panels, areas, etc. are exaggerated for clarity. Throughout this specification, the same reference signs denote the same elements. It should be understood that when an element is referred to as being “on” or “connected to” another element, it may be directly on or connected to another element, or there may be other elements therebetween. On the contrary, when an element is referred to as being “directly on” or “directly connected to” another element, there is no element therebetween. As used herein, “connection” may refer to a physical and/or electrical connection. In addition, “electrical connection” or “electrical coupling” may refer to both direct electrical contact and indirect connections through intermediate components.

The directional terminology used herein is intended to provide detailed descriptions and is not limiting to the present invention. For example, the relative terms “lower”, “upper”, and the like are merely used to describe the relative orientation between one and another element in the figures, depending on the specific viewing angle of the figures. Furthermore, ordinal terms such as “first”, “second”, and “third” as used in the specification are solely intended to modify elements for clarity of distinction, and do not imply any chronological order, priority, or sequence of processing or operation among the elements.

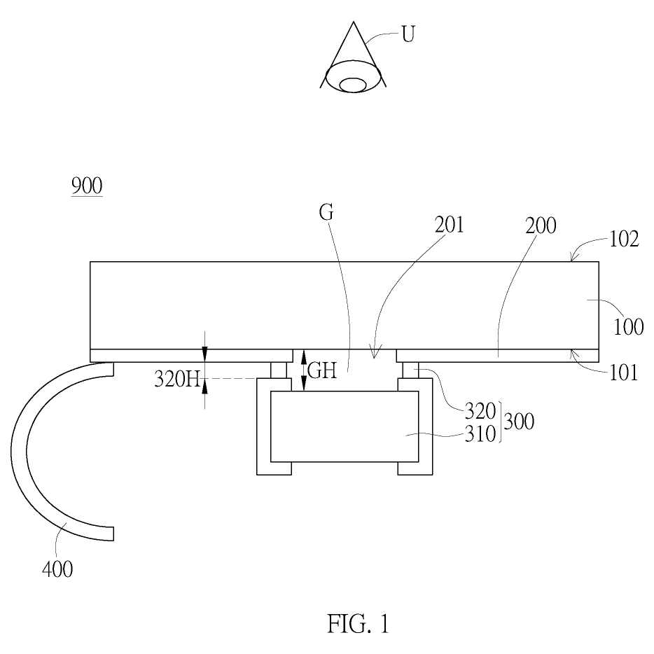

In the embodiment shown in FIG. 1, the display device 900 includes a substrate 100, a wiring layer 200, one or more light-emitting units 300, and a flexible circuit layer 400. The substrate 100 has a light-receiving surface 101 and a light-emitting surface 102 disposed on opposite sides. The substrate 100 may be a transparent board, including, but not limited to, a glass substrate, which allows light to enter the light-receiving surface 101 of the substrate 100 into the substrate 100 and emits from the light-emitting surface 102. The wiring layer 200 is disposed on the light-receiving surface 101 of the substrate 100, wherein a predetermined circuit pattern (not shown in the figures) may be formed by electroplating, etching, chemical deposition, or the like. The light-emitting units 300 are disposed on the light-receiving surface 101 of the substrate 100 and each includes a light-emitting chip 310 and one or more pins 320. Each pin 320 is electrically connected to the light-emitting chip 310 and the wiring layer 200. For example, the pin 320 may be soldered to the wiring layer 200, or a soldered point itself may serve as the pin 320. In other words, the light-emitting unit 300 may be fixed to the substrate 100 through the pin 320.

Preferably, a gap G may be provided between the light-emitting chip 310 and the light-receiving surface 101. In this embodiment, the gap G may be filled with air, and light emitted from the light-emitting chip 310 may pass through the gap G and enter the substrate100. In other embodiments, the gap G may be filled with other gas including nitrogen, argon, or the like, ensuring optical performance while simultaneously preventing oxidation of the light-emitting chip 310, but the practical applications are not limited thereto. In other words, light emitted from the light-emitting chip 310 may directly enter the light-receiving surface 101 of the substrate 100 without passing through other components therebetween. The light-emitting surface 102 of the substrate 100 is configured to face the user, wherein the substrate 100 can support the light-emitting units 300 while simultaneously acting as a protecting layer of the light-emitting units 300; hence, additional protecting layers are not required. Moreover, the pin 320 or wiring disposed on the light-receiving surface 101 of the substrate 100 is less possible to break during joining or installation of one or more substrates 100, enhancing robustness of the display device 900.

The flexible circuit layer 400, which is configured to communicate with other modules for controlling the light-emitting units 300, may be electrically connected to the wiring layer 200 while avoiding interference with the optical path of the light-emitting chip 310. For example, the flexible circuit layer 400 may be disposed on an edge of the substrate 100. Based on this configuration, the component quantity and arrangement density on the substrate 100 can be reduced, improving optical transparency and facilitating installation of the light-emitting units 300.

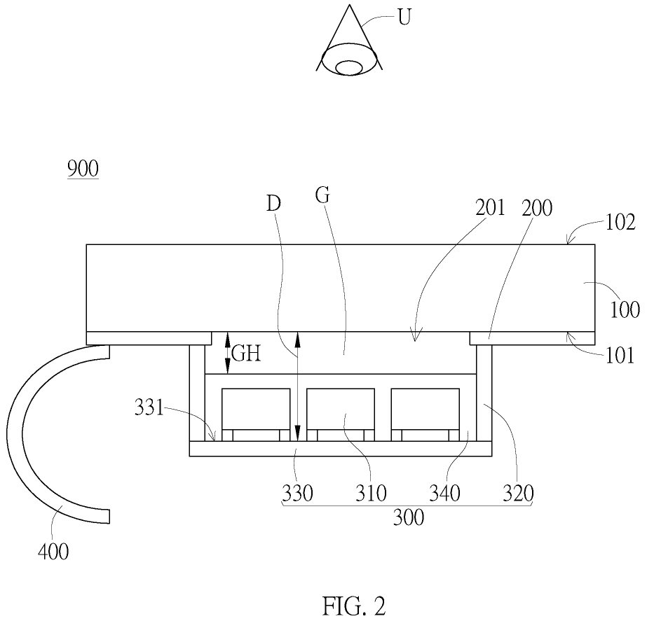

In the embodiment shown in FIG. 2, each light-emitting unit 300 of the display device 900 includes a circuit board 330, at least one light-emitting chip 310, an encapsulation layer 340, and at least one pin 320. The circuit board 330 has a first side 331 facing toward the light-receiving surface 101. The one or more light-emitting chips 310 are disposed on a first side 331 of the circuit board 330 and electrically connected to the circuit board 330. For example, each light-emitting unit 300 may have a plurality of the light-emitting chips 310, including red, green, and blue LEDs, to display various colors. Based on different applications and needs, the set of light-emitting chips 310 in each light-emitting unit 300 may vary. For example, each light-emitting unit 300 may have a plurality of pixels, wherein each pixel includes a plurality of light-emitting chips 310. The encapsulation layer 340 covers the surface of the light-emitting chips 310 facing toward the light-receiving surface 101 for both protection and fixation of the light-emitting chips 310. The pins 320 are electrically connected to the circuit board 330 and the wiring layer 200, enabling electrical connection between the corresponding light-emitting chip 310 and the wiring layer 200. A gap G may be provided between the encapsulation layer 340 and the light-receiving surface 101. Light emitted from the light-emitting chip 310 may pass through the encapsulation layer 340 and the gap G and then enter the light-receiving surface 101 of the substrate 100, wherein no other component is present in the optical path therebetween. Similar to the embodiment mentioned above, the display device 900 includes a flexible circuit layer 400 electrically connected to the wiring layer 200.

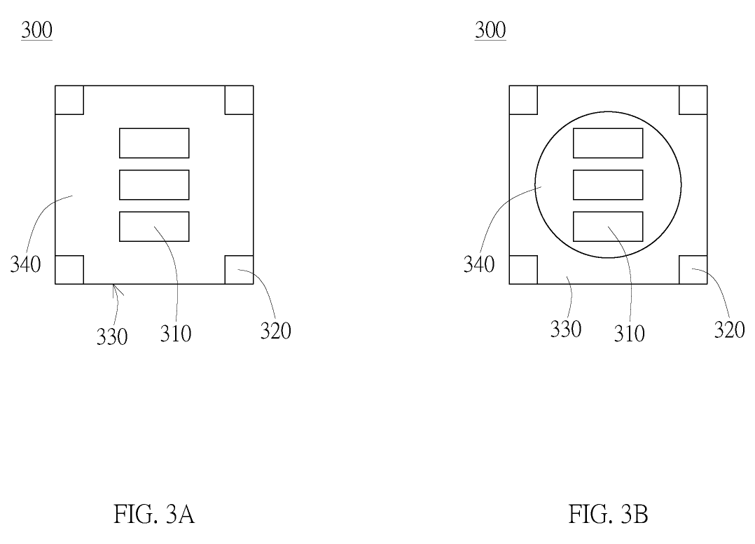

Hereinafter, the manufacturing process of the light-emitting units 300 is illustrated with reference to FIGS. 3A and 3B.

In the embodiment shown in FIG. 3A, the light-emitting chip 310 may be soldered to the first side 331 (referring to FIG. 2) of the circuit board 330; then, the pins 320 may be soldered to the circuit board 330 and extend away from the first side 331; afterward, the encapsulation layer 340 may be formed by dispensing encapsulating materials on the surface of the light-emitting chip 310 and the first side 331 of the circuit board 330. The pins 320 may be located outside the encapsulation layer 340 and at least partially supported by the encapsulation layer 340. For example, the pins 320 may be partially embedded in the periphery of the encapsulation layer 340.

On the contrary, in the embodiment shown in FIG. 3B, the installation sequences may be altered. The light-emitting chip 310 may be soldered to the circuit board 330 followed by the formation of the encapsulation layer 340 covering the light-emitting surface of the light-emitting chip 310. Then, the pins 320 may be soldered to the circuit board 330, wherein the pins 320 may be in contact with or separated from the encapsulation layer 340.

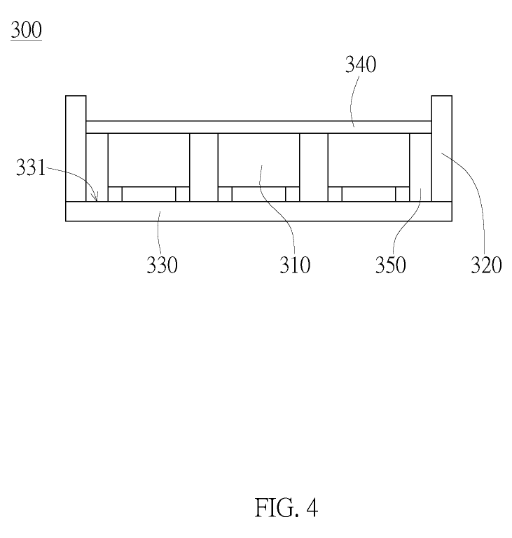

As shown in FIG. 4, a shielding layer 350 such as a black resin layer may be disposed between adjacent light-emitting chips 310. The shielding layer 350 may be used to absorb stray light and optically isolate the light-emitting chips 310 emitting light with different colors, thereby enhancing color saturation and display accuracy. In the manufacturing process, after the light-emitting chips 310 are soldered to the first side 331 of the circuit board 330, the shielding layer 350 may be formed by dispensing shielding materials between the light-emitting chips 310. The shielding layer 350 may not extend beyond the light-emitting surface of the light-emitting chips 310 in the normal direction of the light-emitting surface. Then, the encapsulation layer 340 may be formed on the light-emitting surface of the light-emitting chips 310 and the upper surface of the shielding layer 350.

As shown in FIGS. 1 and 2, the gap G between the light-emitting units 300 (specifically, the light-emitting chips 310 or the shielding layer 350 thereof) and the light-receiving surface 101 may have a height GH in the normal direction of the light-receiving surface 101, wherein the height GH may be less than or equal to 200μm.

In the embodiment shown in FIG. 1, the pin 320 may extend from the upper side (that is, the side close to the substrate 100) of the light-emitting chip 310 toward the light-receiving surface 101, wherein the height 320H of the pin 320 in the normal direction of the light-receiving surface 101 is close to the height GH of the gap G. Thus, the height 320H of the pin 320 may be less than or equal to 200μm.

In the embodiment shown in FIG. 2, the distance D between the circuit board 330 and the light-receiving surface 101 may be greater than or equal to 40μm and less than or equal to 200μm. The distance D between the circuit board 330 and the light-receiving surface 101 may be close to the height of the pin 320.

As shown in FIGS. 1 and 2, the flexible circuit layer 400 such as a Chip On Film (COF) may include signal transmission lines and electronic driving elements (not shown in the figures) for transmitting electrical signals and controlling the brightness or color conditions of the light-emitting units 300. The flexible circuit layer 400 may be connected to an edge of the wiring layer 200 and extend away from the light-receiving surface 101. The flexible circuit layer 400 may bend toward the backside of the light-emitting chips 310 (that is, the side relatively away from the light-receiving surface 101) for connection with other control modules. Based on this configuration, the quantity of electronic components on the substrate 100 can be reduced, preventing obstruction of light emission from the light-emitting units 300, thereby increasing the active display area of the display device.

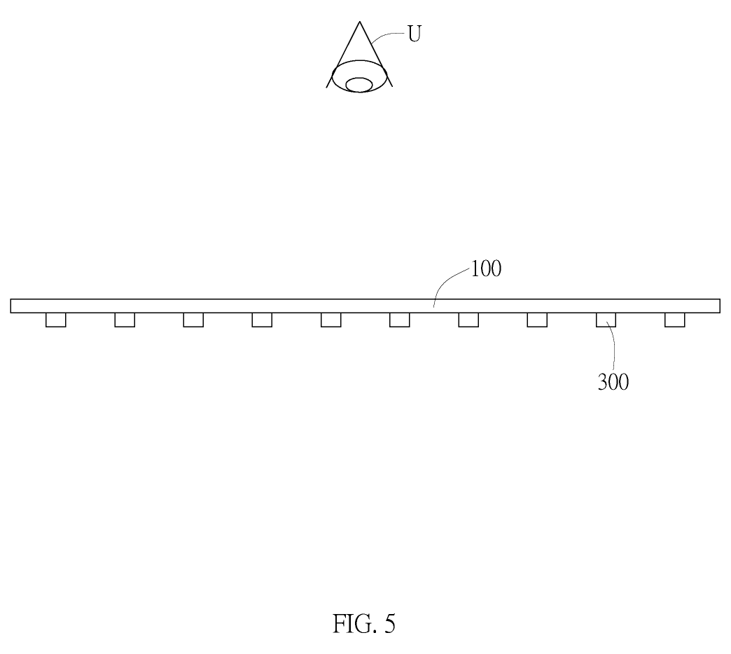

In the embodiment shown in FIG. 5, the display device 900 may include a plurality of light-emitting units 300 arranged in an array to display an integrated image. The length and width of each light-emitting chip 310 (referring to FIGS. 1 and 2) in the light-emitting units 300 may be less than or equal to 500μm, for presenting fine-detail images. For example, the light-emitting chips 310 may be Mini LEDs or Micro LEDs.

In addition, referring to FIGS. 1 and 2, the wiring layer 200 may have perforated regions 201 corresponding to each light-emitting chip 310, allowing light emitted from the light-emitting chips 310 to directly enter the substrate 100 without passing through the wiring layer 200. In other embodiments, the wiring layer 200 may be formed with transparent conducting materials such as Indium tin oxide (ITO), preventing obstruction of light emission from the light-emitting chips 310. The user U may receive the display images from the light-emitting surface 102 of the substrate 100. Furthermore, the display device 900 may have a transparent casing (not shown in the figures), allowing the user U to view the scene on the opposite side of the display device 900 through the transparent substrate 100 and casing.

In summary, the present invention provides a display device with light-emitting units and wirings on the side of the substrate opposing the user. Therefore, the substrate can serve both supporting and protective functions, simplifying the overall structure and manufacturing process of the display device. This configuration also prevents damage to the light-emitting units or wirings caused by external forces or objects from the user side during assembly, transportation, or operation. Meanwhile, by rendering transparent of the substrate and the wiring layer, optical obstruction of the light-emitting units is prevented, thereby increasing the active display area and enhancing the applicability of the display device in various scenarios.

The present invention has been described with various embodiments above. However, these embodiments are merely exemplary and should not be construed as limiting the scope of the invention. On the contrary, various modifications and alterations that can be made without departing from the spirit and scope of the invention are intended to fall within the scope of the present invention.

What is claimed is:

1. A display device comprising:
a substrate having a light-receiving surface and a light-emitting surface disposed on opposite sides;
a wiring layer disposed on the light-receiving surface;
a light-emitting unit disposed on the light-receiving surface and configured to emit light into the substrate, the light-emitting unit including:
a light-emitting chip, and
a pin electrically connected to the light-emitting chip and the wiring layer; and
a flexible circuit layer electrically connected to the wiring layer and extending away from the light-receiving surface.

2. The display device of claim 1, wherein the pin is extending from the light-emitting chip toward the light-receiving surface, and a height of the pin in a direction pointing toward the light-receiving surface is less than or equal to 200 μm.

3. The display device of claim 1, further comprising a plurality of the light-emitting units arranged in an array on the light-receiving surface.

4. The display device of claim 1, wherein the substrate is a glass substrate.

5. The display device of claim 1, wherein the wiring layer is formed on the light-receiving surface of the substrate by electroplating.

6. The display device of claim 1, wherein the wiring layer has a perforated region corresponding to the light-emitting chip.

7. The display device of claim 1, wherein a length and a width of the light-emitting chip are less than or equal to 500μm.

8. The display device of claim 1, wherein a gap is provided between the light-emitting chip and the light-receiving surface, light emitted from the light-emitting chip passes through the gap and enters the substrate, and a height of the gap in a normal direction of the light-receiving surface is less than or equal to 200μm.

9. A display device comprising:
a substrate having a light-receiving surface and a light-emitting surface disposed on opposite sides of the substrate;
a wiring layer disposed on the light-receiving surface;
a light-emitting unit disposed on the light-receiving surface and configured to emit light into the substrate, the light-emitting unit including:
a circuit board having a first side facing toward the light-receiving surface,
a light-emitting chip disposed on the first side of the circuit board and electrically connected to the circuit board,
an encapsulation layer covering a surface of the light-emitting chip facing toward the light-receiving surface, and
a pin electrically connected to the circuit board and the wiring layer; and
a flexible circuit layer electrically connected to the wiring layer and extending away from the light-receiving surface.

10. The display device of claim 9, wherein a distance between the circuit board and the light-receiving surface is greater than or equal to 40 μm and less than or equal to 200 μm.

11. The display device of claim 9, further comprising a plurality of the light-emitting units arranged in an array on the light-receiving surface.

12. The display device of claim 9, wherein the substrate is a glass substrate.

13. The display device of claim 9, wherein the wiring layer is formed on the light-receiving surface of the substrate by electroplating.

14. The display device of claim 9, wherein the wiring layer has a perforated region corresponding to the light-emitting chip.

15. The display device of claim 9, wherein a length and a width of the light-emitting chip are less than or equal to 500μm.

16. The display device of claim 9, wherein a gap is provided between the encapsulation layer and the light-receiving surface, light emitted from the light-emitting chip passes through the encapsulation layer and the gap and enters the substrate, and a height of the gap in a normal direction of the light-receiving surface is less than or equal to 200μm.
